(19) United States
(12) Patent Application Publication
(10) Pub. No.: US 2018/0132357 A1
(43) Pub. Date: May 10, 2018

(54) DEVICE AND METHOD FOR PRODUCING PRINTED CIRCUIT BOARDS FOR ELECTRICAL AND/OR ELECTRONIC CIRCUITS

(71) Applicant: Jan FRANCK, Weidenberg (DE)

(72) Inventor: Jan FRANCK, Weidenberg (DE)

(21) Appl. No.: 15/564,359

(22) PCT Filed: Apr. 13, 2016
(86) PCT No.: PCT/IB2016/000465

§ 371 Date: Oct. 4, 2017

(30) Foreign Application Priority Data
Apr. 13, 2015 (DE) 10 2015 004 508.3

(51) Int. Cl. H05K 3/04; B41J 2/32; H05K 1/02

(52) U.S. Cl. CPC H05K 3/04; H05K 1/02; B41J 2/32

(57) ABSTRACT

The invention relates to a method for manufacturing printed circuit boards for electrical and electronic circuits, comprising an electrically nonconductive substrate and electrically conductive tracks applied thereon, wherein the electrically conductive tracks are imprinted on the substrate according to the desired conductor track layout under the influence of heat. The invention further relates to a device for manufacturing printed circuit boards for electrical and electronic circuits, comprising an electrically nonconductive substrate and electrically conductive tracks applied thereon, including a printing head for selectively heating an electrically conductive print medium according to the desired conductor track layout, in order to transfer this print medium onto the substrate.

### REFERENCE TO PENDING PRIOR PATENT APPLICATIONS

This patent application claims benefit of International (PCT) Patent Application No. PCT/IB2016/000465, filed 13 Apr. 2016 by Jan Franck for DEVICE AND METHOD FOR PRODUCING PRINTED CIRCUIT BOARDS FOR ELECTRICAL AND/OR ELECTRONIC CIRCUITS, which claims benefit of German Patent Application No. DE 10 2015 004 508.3, filed 13 Apr. 2015, which patent applications are hereby incorporated herein by reference.

### FIELD OF THE INVENTION

The invention is directed to a method for manufacturing printed circuit boards for electrical and electronic circuits, comprising an electrically nonconductive substrate and electrically conductive tracks applied thereon, and a device for manufacturing printed circuit boards for electrical and electronic circuits, comprising an electrically nonconductive substrate and electrically conductive tracks applied thereon.

### BACKGROUND OF THE INVENTION

Printed circuit boards for electronic circuits are typically manufactured from a copper-coated substrate by etching away the copper after the desired conductor tracks have been transferred to the copper layer and have thus been selectively sealed, so that the copper beneath the sealed areas of the copper is not removed. However, this method is comparatively time-consuming, since the etching operation proceeds at only a limited speed.

### SUMMARY OF THE INVENTION

The disadvantages of the described prior art have led to the underlying object of the invention, to refine a method and a device for manufacturing conductor tracks for electrical and/or electronic circuits in such a way that the manufacture is preferably rapid and can take place without extended processing times.

For a generic method, this object is achieved in that the electrically conductive tracks are transferred to, i.e., imprinted on, the substrate according to the desired conductor track layout, under the influence of heat on an electrically conductive printing medium.

The invention does not start from a substrate coated with copper on the conductor track side, as in the prior art, but, rather, starts from a bare, electrically nonconductive substrate. The pattern of the conductor tracks is selectively imprinted thereon according to the desired conductor track layout. An electrically conductive printing medium, for example a compound containing silver, is used. However, this compound or this printing medium is not pressed by a print head or applied by means of a doctor blade or the like; instead, carrier material which is spread over the substrate to be imprinted is situated in a planarly distributed state on a film or the like. By selectively heating individual parts of the planarly distributed printing compound, the latter is then transferred to the substrate situated directly underneath or adjacently, where the printing compound resolidifies precisely in the desired pattern. A print head is hereby used that is provided only with individual, approximately punctiform heating elements that are preferably adjacently arranged in a row. The print head does not come into direct contact with the compound to be printed, since the carrier material having the printing compound is still situated in between. For this reason, large quantities of printed circuit boards may be imprinted without the print head becoming worn or only soiled.

In addition or as an alternative to silver as the electrically conductive component of the printing medium, other materials may be used, in particular metals such as aluminum, which has good electrical conductivity with a moderate melting point, as well as zinc or tin. All of these metals have melting points far below 1000° C., and may therefore be more easily heated to their melting point than silver, for example. The electrically conductive material could be applied to the carrier film in the form of nanoparticles. However, it is preferred according to the invention to apply the metal in question to the carrier film by vapor deposition. Of course, this is also possible with higher-melting materials such as silver or copper. For protection from oxidation, base, vapor-deposited metals may be sealed by a cover film which covers the metal, vapor-deposited on the carrier film, on the side of the metal that is initially still free.

All metals and metal alloys, for example those substances having a melting point of 1800° C. or lower, preferably having a melting point of 1500° C. or lower, more preferably having a melting point of 1200° C. or lower, in particular having a melting point of 1000° C. or lower, are also usable in principle as an electrically conductive component in the printing medium.

This electrically conductive material may be incorporated as a component in the printing medium, which then contains additional, preferably lower-melting, components such as binders, plasticizers, etc. However, it is also conceivable to apply such an electrically conductive substance in pure form to a film-like carrier substrate by vapor deposition, or to affix same adhesively, in particular in the form of nanoparticles, and to optionally cover with a further film that melts at a lower temperature than the nanoparticles.

However, the material in question should also be meltable by a print head at specific points. The lower the melting point of the material in question, the more easily this procedure may be carried out. In this regard, aluminum, having a melting point of 660° C. and an electrical conductivity of 35 m/ohm*mm², represents a good compromise. Zinc has a melting point of only 419° C. with an electrical conductivity of 16.9 m/ohm*mm²; for tin, the melting point is just 232° C., and the electrical conductivity is still 8.7 m/ohm*mm².

While conventional thermal print heads may thus be used for tin or zinc, for metals having higher melting points, such as aluminum or silver, hotter, specialized thermal print heads should be used. Instead of using heating resistors for generating localized heat spots, it would also be conceivable to use laser beams, for example, which are directed onto the individual print spots by means of optical aids such as optical fibers in a print head. Laser beams may also be switched on and off very quickly, and may be focused very precisely on individual spots, so that the energy density that is necessary for higher melting points may be generated with very little effort.

Heating the electrically conductive printing medium by means of a thermal print head has the advantage of a very sharp contrast, so that conductor tracks having extremely sharp edges may be reliably produced. In contrast to “cold” printing methods such as inkjet printers, for example, the individual metal particles are fused to form a combined matrix, and in fact form a uniform conductor without transfer resistances, whereas for strictly imprinting with nanoparticles, the overall conductivity is still dependent on the transfer resistances at the contact points, and in particular on whether there are even enough contact points at all.

On the other hand, within the scope of the invention there is also the option for operating at a temperature below the melting temperature and only sintering the individual metal particles together, i.e., fusing them at the surface, until they flow together at a specific point. For this purpose, temperatures that are 10 to 20% below the melting point of the material in question, i.e., only 528° C. to 594° C. for aluminum, for example, are usually sufficient. It may also be sufficient to design the thermal print head only for temperatures between 80% and 90% of the melting temperature.

To further relieve the print head, it may be provided that the substrate to be imprinted is preheated to a temperature just below the required temperature, i.e., the melting temperature or the sintering temperature, so that the print head itself only has to overcome the remaining temperature difference. The most reliable approach is for the preheat temperature to be below the sintering temperature, so that in no event does undesirable sintering start to occur prior to the actual printing operation. The task of the thermal print head is then to locally heat the metal layer, which has been preheated to a temperature just below the sintering temperature (i.e., to 70% of the melting temperature, for example), to above the melting temperature, for example to 110% of the melting temperature. This difference is then in the range of approximately 40% of the melting temperature. In such cases, silver, having a typical melting point of 960° C., could also be processed with a print head whose heating capacity is only approximately 384° C. to 400° C., which may be readily achieved with resistor heating elements, provided that the overall print head is designed for a continuous operating temperature that corresponds to the melting point of the metal to be processed, or is slightly higher, for example 110% of the melting point. Heating wires or coils made of tungsten, for example, have a melting point of 3380° C., and therefore can easily withstand temperatures of 1000° C. For example, a ceramic material having sufficient heat resistance could be used as the material for the chassis of a print head.

In addition, it may be advantageous for this method when, prior to the actual printing operation, the metallized side of the carrier film is brought into close contact with the substrate to be imprinted, so that the thin metal layer is appropriately preheated. If necessary, this could be achieved using a pressure roller.

For this purpose, the substrate to be imprinted may optionally be transported through an oven beforehand. On the other hand, the surface to be imprinted could also be exposed to heat radiation, for example infrared radiation or microwave radiation.

The carrier film for the metal coating itself should be designed at least for the preheat temperature or for the sintering temperature of the metal, so that it does not lose its structural stability prior to the printing operation. Films made of polytetrafluoroethylene (Teflon) or smooth carbon films, or so-called ultrathin glass, would be suitable, depending on the metal being used.

Carbon films should be processed under a protective gas, since introduction of oxygen may result in softening of the carbon.

Ultrathin glass is a glass film having a thickness in a range of only 20 μm to 100 μm, typically approximately 50 μm. Such glass is very flexible due to its small thickness. It has the further advantage that it is transparent, and thus allows the heat radiation of a thermal print head to pass through unhindered. Quartz glasses having a high SiO₂ content, for example 70% by weight SiO₂ or greater, preferably 80% by weight SiO₂ or greater, in particular 90% by weight SiO₂ or greater, are thermally stable up to temperatures of 1500° C.

When such a film made of ultrathin glass having a high SiO₂ content is used, it is also possible to fuse silver onto a substrate without damaging the film. After the printing operation, the film is rewound, undamaged, onto a laydown spool.

Of course, it is also possible to operate at a maximum temperature below the sintering temperature. However, the individual metal particles then do not fuse together to form a combined matrix, and therefore transfer resistances remain at the contacts between adjacent metal particles. In this procedure, however, a low-melting adhesive film should then be used between the carrier film and the metal particles applied thereto, which disintegrates, i.e., melts or sublimes, under the influence of the thermal print head, and then releases the previously retained metal particles, which may then deposit on the substrate. Of course, the carrier film itself could also have a correspondingly low melting point. However, it would then have to be ensured that the film does not completely disintegrate, and remains at least in areas, and may thus be rewound, at least in part, onto the laydown spool.

In addition, the invention provides the option to imprint electrically nonconductive layers in the form of an electrically nonconductive printing medium onto the substrate, in particular under the influence of heat on the printing medium. It is thus possible to also seal the conductor tracks, using the same system.

For this purpose, it would be advisable to use a material having a relatively high melting point as the nonconductive layer, for example a film made of polytetrafluoroethylene (Teflon) or the above-mentioned ultrathin glass; however, it is preferred to use a type having a reduced SiO₂ content and thus a lower melting point that is within the processing range of the thermal printing device, i.e., preferably at or below the melting point of the metal applied therebeneath.

A second level may optionally be imprinted on a lowermost conductor track level that is sealed in this way, optionally using the same metal as in the first layer, or using a material having a lower melting point than the electrically nonconductive sealing layer.

An insulating layer may optionally once again be applied thereto, and if necessary, also further conductor track levels, each separated from one another in areas by nonconductive layers. However, it should be ensured that the melting points of newly imprinted layers are preferably not appreciably above the melting point of the layer situated therebeneath, or optionally are even at a lower temperature. When the melting temperatures are the same, melting through to lower layers may possibly be avoided by using short operating times.

In addition, electrical and/or electronic components such as resistors, voltage dividers, etc., may likewise be imprinted on the substrate by means of a resistive printing medium, and capacitors may be imprinted by providing, one on top of the other, a bottom layer made of an electrically conductive printing medium, a middle layer made of a nonconductive, for example dielectric, printing medium, and a top layer made of an electrically conductive printing medium, etc. Coils may likewise be imprinted as spiral coils, and optionally also components having other properties, such as hot or cold conductors, or also (electro)luminescent elements.

Laminated paper having an FR2 material code (FR stands for fire retardant) is suitable as a printed circuit board substrate. Mats, in particular glass fiber mats, having an FR4 material code and that are impregnated with a resin, for example epoxy resin, are also used. FR4 materials have better creep resistance and better high-frequency properties, as well as lower water absorption, than laminated paper.

In addition, a printed circuit board substrate having other materials as the base material is available for special applications. Mentioned in particular in this regard is Teflon, as well as aluminum oxide or ceramics, in particular in the form of low-temperature cofired ceramics (LTCC) and/or high-temperature cofired ceramics (HTCC), in particular also for applications in high-frequency technology. The above-mentioned materials are used to produce rigid printed circuit board substrates which thus have little or no flexibility.

In contrast, films, in particular polyester films, are suitable as flexible printed circuit board substrates.

Printed circuit board substrates subject to more stringent requirements regarding cooling or heat dissipation may have one or more cores made of a metal such as aluminum or copper, or made of a metal alloy.

The invention further relates to a device for manufacturing printed circuit boards for electrical and electronic circuits, comprising an electrically nonconductive substrate and electrically conductive tracks applied thereon, which includes a print head for selectively heating an electrically conductive printing medium according to the desired conductor track layout, in order to transfer this printing medium onto the substrate. This device includes on the one hand a device for providing a film that is coated with the printing medium, for example wound around a core, and unwinding this film, coated with the printing medium, at that location and placing it on or applying it to the substrate, and on the other hand includes a printing device in the form of a thermal print head having a plurality of independently heatable miniature elements, each of which heats a small area of the printing medium on the film, thus transferring the heated printing medium onto the electrically nonconductive substrate in order to produce a conductor track or the like at that location.

The electrically nonconductive substrate to be imprinted may preferably be transported past the printing device. The film-like carrier material with the printing medium initially planarly applied thereto may be transported at a comparable speed in parallel to the substrate to be imprinted, while the print head instead comes to a standstill or moves only transversely with respect to the transport direction. The planar carrier material is preferably unwound between two spools, i.e., from a supply spool onto a laydown spool, from or with which it may then be disposed of or recycled.

Multiple printing devices may be provided in succession in the transport direction of the substrate, each having a print head and a supply spool and laydown spool for a film with a specific printing medium, i.e., with an electrically conductive printing medium or with an electrically nonconductive printing medium, with a dielectric printing medium, or with an (electro)luminescent printing medium, etc.

By printing these various printing media above and beside one another, each printed circuit board having any desired conductor track layout may be manufactured by printing, optionally at the same time with various components such as coils, capacitors, resistors, etc. If discrete components such as transistors, microprocessors, or plug-in contacts are also necessary, soldering tags or soldering areas may likewise be imprinted for this purpose.

By use of the invention, more or less hard printed circuit boards are preferably imprinted, since with these printed circuit boards the imprinted conductor track structures are not subjected to appreciable bending stress, and therefore are not susceptible to wear.

### BRIEF DESCRIPTION OF THE DRAWINGS

Further features, particulars, advantages, and effects based on the invention result from the following description of one preferred embodiment of the invention, and with reference to the drawings, which show the following:

FIG. 1 shows a side view of a device according to the invention for manufacturing printed circuit boards for electrical and electronic circuits, including a thermal print head; and

FIG. 2 shows a view of the bottom side of the thermal print head from FIG. 1, in the direction of the arrows II-II.

### DETAILED DESCRIPTION OF THE PREFERRED EMBODIMENTS

Within the scope of the invention, for manufacturing printed circuit boards for electrical and electronic circuits, a device 1 is used which has a print head 2 for selective, localized heating of individual print spots or pixels of an electrically conductive printing medium 3 that is present in planar form, so that the printing medium is sintered, fused on, or melted at the selected print spots or pixels, and after being transferred to a substrate 4 situated underneath or adjacently, the printing medium resolidifies there in the form of a combined matrix, resulting in the desired conductor tracks, in the ideal case without transfer resistances.

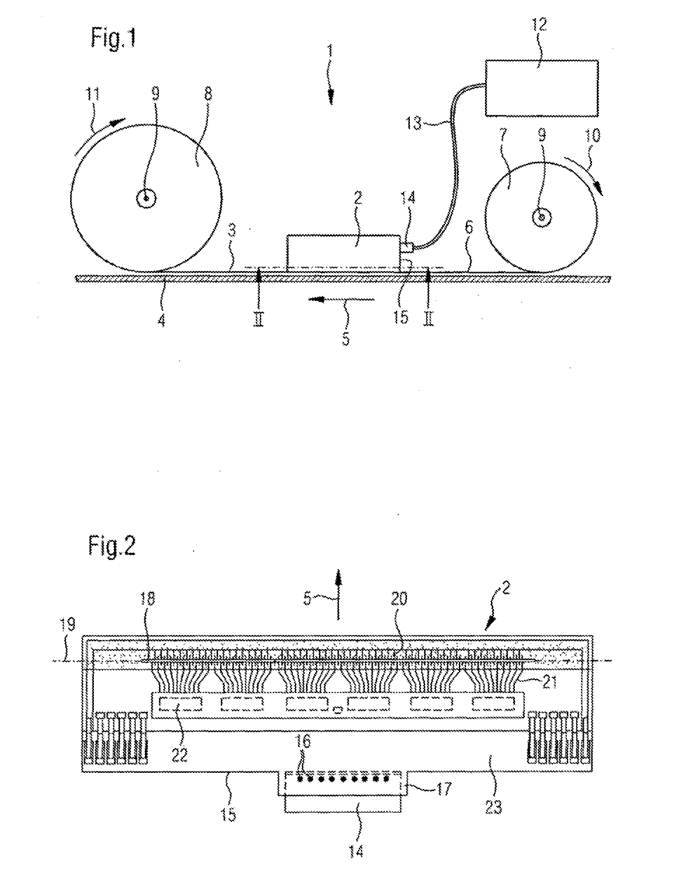

A transport device for setting the printed circuit board substrate 4 to be imprinted in motion 5 with respect to the print head 2 is not illustrated in FIG. 1. This may be a roller track or a conveyor belt, or also an oscillating plate.

In addition, a heating device may be situated in front of the print head, viewed in the transport direction 5, in order to preheat the printed circuit board substrate 4, thus reducing the heat that is to be generated by the thermal print head 2. This could be a thermal radiator along which the flat, in particular plate-shaped, substrate 4 is moved. On the other hand, it is also sufficient to preheat the printed circuit board material 4 in an oven, for example, from which it may then be removed, in a batchwise manner, for example, at the correct temperature.

The printing medium 3 is situated on the side or surface of a film-like carrier material 6 which faces the substrate 4, and which extends between the print head 2 and the substrate 4, at which location it may be transported synchronously with the transport movement 5.

The carrier material 6 preferably has the shape of a long strip that may be unwound from a supply spool 7 and a laydown spool 8.

With regard to the unwinding speed, it should also be ensured that it is preferably completely synchronous with the transport movement 5 of the substrate 4, so that preferably no relative movement occurs between the flat elements, namely, the substrate 4 on the one hand and the carrier material 6 on the other hand. This requires that, among other things, the supply spool 7 is situated upstream from the print head 2 with respect to the transport direction 5 of the substrate 4, while the laydown spool 8 is situated downstream from the print head 2.

The axles or shafts 9 of the supply spool 7 on the one hand and of the laydown spool 8 on the other hand may be adjustable in a direction perpendicular to the level of the substrate 4 to be imprinted, so that in the area of the print head 2 the section of the carrier film 6 bearing the printing medium 3 is always oriented parallel to the substrate 4, and preferably rests flatly against same.

When the supply spool and laydown spool 7, 8 are pressed against the substrate 4 in a frictionally locked manner, this frictional locking ensures that the peripheral speed 10, 11 of the supply spool and laydown spool 7, 8 is always equal to the transport speed 5 of the substrate 4, regardless of the instantaneous diameters of these two spools 7, 8, which in fact continuously change in the course of unwinding from the supply spool 7 to the laydown spool 8. Of course, such synchronicity between the spool peripheral speeds 10, 11 on the one hand and the transport speed 5 on the other hand could also be achieved by suitable control or regulation, which, however, means increased design complexity. In contrast to the first embodiment, where the supply spool and laydown spool 7, 8 are passively driven, i.e., their drive is received by the substrate 4 to be imprinted, in the latter case it would also be necessary to provide (separate) drives for the two spools 7, 8.

The print head 2 is controlled by a control device 12, preferably according to a conductor track layout stored therein. The control device 12 may be connected to the print head 2 via one or more preferably electrical control lines 13 that maintain contact with the print head 2 via a plug-in device 14, for example.

FIG. 2 illustrates one possible embodiment of the print head 2 in a more detailed view. A socket 17, provided with plug-in contacts 16, for inserting the plug 14 of the control device 12 is apparent on one side, for example on an upstream end-face side 15 of the print head 2.

The actual thermal heating device 18 of the print head 2 extends perpendicularly with respect to the transport direction 5 of the substrate 4, preferably along a straight line 19. This may be a linearly extending heating conductor 18 made of a very resistive material, for example tungsten, which is also the material of the heating wires in light bulbs.

A large number of feed lines 20, 21 branch off from this heating conductor 18, preferably in alternation in the transport direction 5 and opposite the transport direction.

Every other one of these feed lines 20, preferably the ones that branch off in the direction 5 opposite from the plug socket 17, are connected to one another and thus short-circuited, and are connected to a shared contact 16, preferably a ground contact at that location.

The remaining feed lines 21, which preferably branch off from the heating conductor 18 in the direction toward the plug socket 17, i.e., preferably opposite the transport direction 5, are each connected to a voltage supply, in particular to a contact pin 16 having a supply voltage, via a semiconductor switch 22.

The individual semiconductor switches 22 may be addressed via a line bus as a component of the feed line 13 and the corresponding plug-in contacts in order to selectively switch them on when the section of the heating conductor 18 associated with a semiconductor switch 22 is to be heated in order to print a pixel at the location in question.

The chassis 23 of the print head 2 is preferably made of ceramic or some other material that is suitable for high temperatures. The melting or softening temperature of this material should in particular be higher than the maximum operating temperature of the heating conductor 18.

In particular when the substrate 4 is preheated to a temperature just below the operating temperature of the heating conductor 18 by means of a heating device, not illustrated, or in an oven, only a small amount of energy needs to be supplied within the print head, so that, due to the additional quantity of heat, the temperature of the section of the heating wire 8 in question increases to the desired operating temperature.

Of course, it would also be possible in principle to use some other energy converter instead of a heating wire 18 to focus the necessary quantity of heat onto a spot of the substrate 4 to be imprinted. A comparatively large quantity of energy could be generated by means of a laser, for example, provided that the laser beam of the laser is guided to the spots in question, depending on the desired conductor track layout, and at that location is directed onto the carrier material 6 or preferably through same, directly into the printing medium 3.

This could take place, for example, by means of a plurality of optical fibers that are coupled on one end to the laser, and that on their other free end are each associated with a pixel or spot. Individual pixels or spots may be selectively heated by controlling, by means of light switches, the luminous flux between the laser and the optical fiber according to the desired conductor track layout.

An optimal energy yield or effectiveness is obtained when a laser in the red and/or infrared spectrum is used, so that the radiant power is delivered predominantly or exclusively as heat radiation.

In addition, so-called fiber lasers, a specialized form of solid-state lasers, appear to be particularly suitable. A doped core of a glass fiber is used as active medium, so that a fiber laser is thus a glass laser having properties of an optical fiber. The laser radiation is conducted by the laser-active fiber, and is highly intensified due to the comparatively long length.

Fiber lasers are generally optically pumped by coupling radiation of at least one diode laser in parallel to the fiber core, into the cladding of the fiber core or into the fiber core itself. A structure having so-called double-clad fibers delivers a higher power output; the pump radiation from the thick cladding passes into the active fiber core in a distributed manner.

Erbium, ytterbium, and/or neodymium may be used as doping elements for the laser-active fiber core. Usually only the middle portion of the glass fiber is doped.

Fiber lasers have electro-optical efficiencies of greater than 30%, as well as excellent beam quality, a long service life, and a compact, maintenance-free, robust design. In pulsed operation, fiber lasers may be used to achieve high peak intensities, and thus a high power density, to generate temperatures above the melting point T_{S} of metals such as silver (T_{S}=961° C.) or copper (T_{S}=1085° C.) at specific points. With this technique, it is thus possible to manufacture even continuous conductor tracks made of copper.

If necessary, multiple printing devices, each having one print head 2 and one supply spool and laydown spool 7, 8, may be situated in succession in the transport direction 5 of the strip- or film-like carrier material 6 in order to print multiple layers of electrically conductive and electrically nonconductive structures one on top of the other, or optionally also structures made of specialized materials such as dielectrics, for example for manufacturing a film capacitor. However, for layers that are to be printed one on top of the other, it should be ensured that structures that are already applied are not remelted, which could result in undesirable short circuits between various layers. Therefore, it is recommended to limit the number of layers that are to be printed one on top of the other, and preferably to laminate multiple substrate layers 4 onto one another which have already been appropriately imprinted in each case.

### LIST OF REFERENCE NUMERALS

1 device
2 print head
3 printing medium
4 substrate
5 transport movement
6 carrier material
7 supply spool
8 laydown spool
9 axle, shaft
10 peripheral speed
11 peripheral speed
12 control device
13 control line
14 plug-in device
15 upstream end-face side
16 plug-in contacts
17 socket
18 heating conductor
19 straight line
20 feed line
21 feed line
22 semiconductor switch
23 chassis

1. A method for manufacturing printed circuit boards for electrical and electronic circuits, comprising an electrically nonconductive substrate and electrically conductive tracks applied thereon, characterized in that the electrically conductive tracks are imprinted on the substrate according to the desired conductor track layout, under the influence of heat on an electrically conductive printing medium.

2. The method according to claim 1, characterized in that the electrically conductive printing medium is heated by means of a thermal print head.

3. The method according to claim 1, characterized in that at least one electrically nonconductive layer in the form of an electrically nonconductive printing medium is imprinted on the substrate, preferably under the influence of heat on the printing medium.

4. The method according to claim 1, characterized in that electrical or electronic components such as resistors, voltage dividers, etc., are likewise imprinted on the substrate by means of a resistive printing medium, and capacitors are imprinted by providing, one on top of the other, a bottom layer made of an electrically conductive printing medium, a middle layer made of a nonconductive printing medium, and a top layer made of an electrically conductive printing medium.

5. A device for manufacturing printed circuit boards for electrical and electronic circuits, comprising an electrically nonconductive substrate and electrically conductive tracks applied thereon, characterized by a print head for selectively heating an electrically conductive printing medium according to the desired conductor track layout, in order to transfer this printing medium onto the substrate.

6. The device according to claim 5, characterized in that the print head has at least one heating device, preferably a heating conductor having a fairly large number of individual sections that can be selectively supplied with current or voltage in order to induce heat at the spot in question and thus print a pixel at that location.

7. The device according to claim 5, characterized in that the print head has at least one heating device, preferably a laser, having a fairly large number of individual optical fiber sections which in each case end at different spots and may be selectively controlled with the beam of the laser in order to induce heat at the spot in question and thus print a pixel at that location.

8. The device according to claim 5, characterized by a transport device for moving the substrate relative to the print head.

9. The device according to claim 8, characterized in that the printing medium is applied to a film like carrier that is unwound from a supply spool, along the substrate to be imprinted, onto a laydown spool.

10. The device according to claim 9, characterized in that the transport speed of the film-like carrier in the area between the supply spool and the laydown spool is equal to the transport speed of the substrate to be imprinted.

11. The device according to claim 5, characterized by multiple printing devices, each having one thermal print head and one supply spool and laydown spool for each strip- or film-like carrier material provided with a printing medium, the printing devices being situated in succession in the transport direction of the substrate to be imprinted.
